(19) United States
(12) Patent Application Publication
(10) Pub. No.: US 2025/0386594 A1
(43) Pub. Date: Dec. 18, 2025

(54) INCREASED CONTACT AREA FOR SELF-ALIGNED GATE ISOLATION

(71) Applicant: International Business Machines Corporation, Armonk, NY (US)

(72) Inventors: Alexander Reznicek, Troy, NY (US); Ruilong Xie, Niskayuna, NY (US); Sagarika Mukesh, ALBANY, NY (US); Tsung-Sheng Kang, Ballston Lake, NY (US)

(21) Appl. No.: 18/742,922

(22) Filed: Jun. 13, 2024

(51) Int. Cl. H01L 27/092; H01L 21/8238; H01L 29/06; H01L 29/417; H01L 29/775; H01L 29/786

(52) U.S. Cl. CPC H10D 84/85; H10D 30/43; H10D 30/6757; H10D 62/121; H10D 64/251; H10D 84/0186; H10D 84/038

(57) ABSTRACT

A microelectronic structure that includes a first nanosheet transistor that includes a first source/drain and a second nanosheet transistor that includes a second source/drain. A first frontside source/drain contact that includes a horizontal section and a protrusion section. The horizontal section of the first frontside source/drain contact is in contact with the flat horizontal frontside surface of the first source/drain. The protrusion section of the first frontside source/drain contact is in contact with the at least one inclined side surface of the first source/drain. A second frontside source/drain contact that includes a horizontal section and at least one protrusion section. The horizontal section of the second frontside source/drain contact is in contact with the flat horizontal frontside surface of the second source/drain. The at least one protrusion section of the second frontside source/drain contact is in contact with the at least one inclined side surface of the second source/drain.

### BACKGROUND

The present invention generally relates to the field of microelectronics, and more particularly to formation of source/drain contacts.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form separate components for each device without defects.

### BRIEF SUMMARY

Additional aspects and/or advantages will be set forth in part in the description which follows and, in part, will be apparent from the description, or may be learned by practice of the invention.

A microelectronic structure that includes a first nanosheet transistor that includes a first source/drain. The first source/drain includes a flat horizontal frontside surface and at least one inclined side surface. A second nanosheet transistor that includes a second source/drain. The second source/drain includes a flat horizontal frontside surface and at least one inclined side surface. The first nanosheet transistor and the second nanosheet transistor are adjacent to each other, where the first source/drain and the second source/drain are aligned with each other through a common axis through a source/drain region. A first frontside source/drain contact that includes a horizontal section and a protrusion section. The horizontal section of the first frontside source/drain contact is in contact with the flat horizontal frontside surface of the first source/drain. The protrusion section of the first frontside source/drain contact is in contact with the at least one inclined side surface of the first source/drain. A second frontside source/drain contact that includes a horizontal section and at least one protrusion section. The horizontal section of the second frontside source/drain contact is in contact with the flat horizontal frontside surface of the second source/drain. The at least one protrusion section of the second frontside source/drain contact is in contact with the at least one inclined side surface of the second source/drain.

A microelectronic structure that includes a first nanosheet transistor that includes a first source/drain. The first source/drain includes a flat horizontal frontside surface and at least one inclined side surface. A second nanosheet transistor that includes a second source/drain. The second source/drain includes a flat horizontal frontside surface and at least one inclined side surface. The first nanosheet transistor and the second nanosheet transistor are adjacent to each other, where the first source/drain and the second source/drain are aligned with each other through a common axis through a source/drain region. A first frontside source/drain contact that includes a horizontal section and a protrusion section. The horizontal section of the first frontside source/drain contact is in contact with the flat horizontal frontside surface of the first source/drain. The protrusion section of the first frontside source/drain contact is in contact with the at least one inclined side surface of the first source/drain. A second frontside source/drain contact that includes a horizontal section and at least one protrusion section. The horizontal section of the second frontside source/drain contact is in contact with the flat horizontal frontside surface of the second source/drain. The at least one protrusion section of the second frontside source/drain contact is in contact with the at least one inclined side surface of the second source/drain. A gate cut located on top of the contact cut, where the gate cut is in contact with a side surface of the first frontside source/drain contact and a side surface of the second frontside source/drain contact.

A microelectronic structure that includes a first nanosheet transistor that includes a first source/drain. The first source/drain includes a flat horizontal frontside surface and at least one inclined side surface. A second nanosheet transistor that includes a second source/drain. The second source/drain includes a flat horizontal frontside surface and at least one inclined side surface. The first nanosheet transistor and the second nanosheet transistor are adjacent to each other, where the first source/drain and the second source/drain are aligned with each other through a common axis through a source/drain region. A first frontside source/drain contact that includes a horizontal section and a protrusion section. The horizontal section of the first frontside source/drain contact is in contact with the flat horizontal frontside surface of the first source/drain. The protrusion section of the first frontside source/drain contact is in contact with the at least one inclined side surface of the first source/drain. A second frontside source/drain contact that includes a horizontal section and at least one protrusion section. The horizontal section of the second frontside source/drain contact is in contact with the flat horizontal frontside surface of the second source/drain. The at least one protrusion section of the second frontside source/drain contact is in contact with the at least one inclined side surface of the second source/drain. A gate cut located on top of the contact cut, where the gate cut is in contact with a side surface of the first frontside source/drain contact and a side surface of the second frontside source/drain contact. A backside surface of the gate cut is wider than a frontside surface of the contact cut.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet transistors, in accordance with the embodiment of the present invention.

FIG. 2 illustrates a cross section X of the nanosheet transistor after the formation of the dummy gate, hardmask, and dielectric pillars, in accordance with the embodiment of the present invention.

FIG. 3 illustrates a cross section Y1 of the gate region after the formation of the dummy gate, hardmask, and dielectric pillars, in accordance with the embodiment of the present invention.

FIG. 4 illustrates a cross section Y2 of the source/drain region after the formation of the dummy gate, hardmask, and dielectric pillars, in accordance with the embodiment of the present invention.

FIG. 5 illustrates a cross section X of the nanosheet transistor after etching the top of the sacrificial layer, in accordance with the embodiment of the present invention.

FIG. 6 illustrates a cross section Y2 of the source/drain region after etching the top of the sacrificial layer, in accordance with the embodiment of the present invention.

FIG. 7 illustrates a cross section X of the nanosheet transistor after removal of the sacrificial separating layer, in accordance with the embodiment of the present invention.

FIG. 8 illustrates a cross section Y1 of the gate region after removal of the sacrificial separating layer, in accordance with the embodiment of the present invention.

FIG. 9 illustrates a cross section Y2 of the source/drain region after removal of the sacrificial separating layer, in accordance with the embodiment of the present invention.

FIG. 10 illustrates a cross section X of the nanosheet transistor after formation of gate spacer, in accordance with the embodiment of the present invention.

FIG. 11 illustrates a cross section Y1 of the gate region after formation of gate spacer, in accordance with the embodiment of the present invention.

FIG. 12 illustrates a cross section X of the nanosheet transistor after etching of the source/drain region, recessing of the sacrificial layers, formation of the inner spacer, and formation of the placeholder trenches, in accordance with the embodiment of the present invention.

FIG. 13 illustrates a cross section Y2 of the gate region after etching of the source/drain region, recessing of the sacrificial layers, formation of the inner spacer, and formation of the placeholder trenches, in accordance with the embodiment of the present invention.

FIG. 14 illustrates a cross section X of the nanosheet transistor after formation of the placeholders and the formation of source/drains, in accordance with the embodiment of the present invention.

FIG. 15 illustrates a cross section Y2 of the gate region after formation of the placeholders and the formation of source/drains, in accordance with the embodiment of the present invention.

FIG. 16 illustrates a cross section X of the nanosheet transistor after formation of the gate, the frontside interlayer dielectric layer and the gate cap, in accordance with the embodiment of the present invention.

FIG. 17 illustrates a cross section Y1 of the gate region after formation of the gate, the frontside interlayer dielectric layer and the gate cap, in accordance with the embodiment of the present invention.

FIG. 18 illustrates a cross section Y2 of the source/drain region after formation of the gate, the frontside interlayer dielectric layer and the gate cap, in accordance with the embodiment of the present invention.

FIG. 19 illustrates a cross section Y2 of the source/drain region after formation of a source/drain cut trench, in accordance with the embodiment of the present invention.

FIG. 20 illustrates a cross section X of the nanosheet transistor after removal of the frontside interlayer dielectric layer from the source/drain region, in accordance with the embodiment of the present invention.

FIG. 21 illustrates a cross section Y2 of the gate region after removal of the frontside interlayer dielectric layer from the source/drain region, in accordance with the embodiment of the present invention.

FIG. 22 illustrates a cross section X of the nanosheet transistor after formation of the shared contacts in the source/drain region, in accordance with the embodiment of the present invention.

FIG. 23 illustrates a cross section Y2 of the gate region after formation of the shared contacts in the source/drain region, in accordance with the embodiment of the present invention.

FIG. 24 illustrates a cross section X of the nanosheet transistor after formation of the contact cuts, in accordance with the embodiment of the present invention.

FIG. 25 illustrates a cross section Y2 of the gate region after formation of the contact cuts, in accordance with the embodiment of the present invention.

FIG. 26 illustrates a cross section X of the nanosheet transistor after backside processing of the nanosheet transistors, in accordance with the embodiment of the present invention.

FIG. 27 illustrates a cross section Y1 of the gate region after backside processing of the nanosheet transistors, in accordance with the embodiment of the present invention.

FIG. 28 illustrates a cross section Y2 of the source/drain region after backside processing of the nanosheet transistors, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards separating merged source/drains from each other and the formation of source/drain contact. Separating the merged source/drains changes the profile of the source/drains as viewed through the source/drain region. The changed profile of the source/drains increases the amount of available surface area that can be used in a connection with the source/drain contacts. The increased contact surface area between the source/drain and the source/drain contacts leads to a lower resistance and better performance of the device.

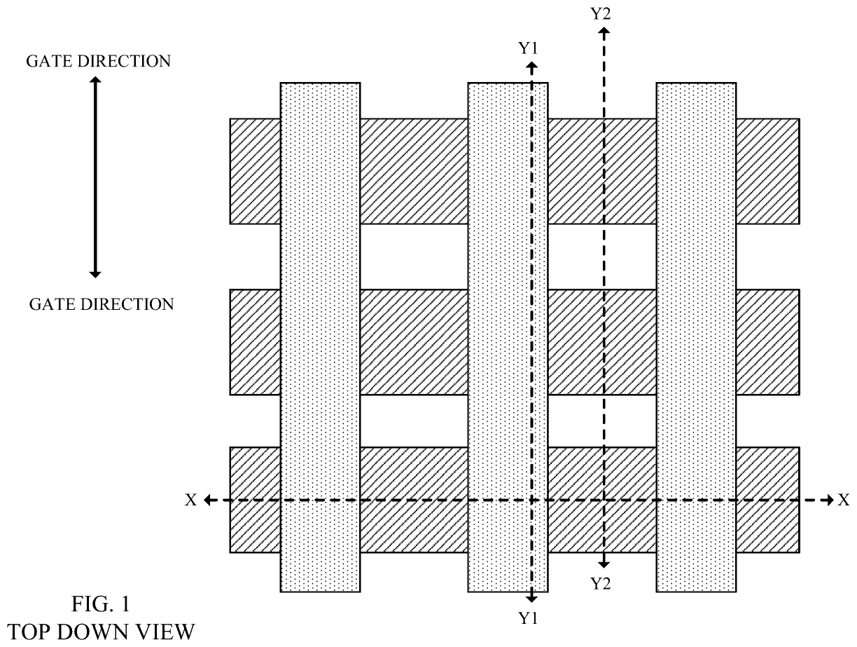

FIG. 1 illustrates a top-down view of multiple devices, in accordance with the embodiment of the present invention. The cross-section X extends horizontally through nanosheet transistors or field-effect-transistors. Cross section Y1 is perpendicular to cross section X, where cross section Y1 is through a gate region that spans across multiple adjacent nanosheet transistors or field-effect-transistors. Cross section Y2 is perpendicular to cross section X, where cross section Y1 is through a source/drain region that spans across multiple adjacent nanosheet transistors or field-effect-transistors. Cross-section X is perpendicular to the gate direction and cross-section Y1 and Y2 are parallel to the gate direction.

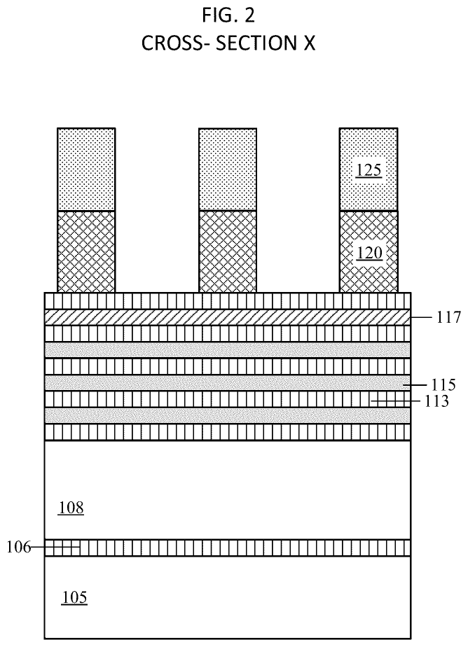

Referring now to FIGS. 2, 3 and 4, a structure is shown during an intermediate step of a method of fabricating after the formation of the after the formation of the of the dummy gate 120, hardmask 125, and dielectric pillars 133G, 133SD. FIG. 2 illustrates the nano stack of the nanosheet transistors that includes a first substrate 105, etch stop 106, second substrate 108, a plurality of layers, a separating sacrificial layer 117, a dummy gate 120, and a hardmask 125, and dielectric pillars 133G, 133SD.

The plurality of layers includes alternating layers that includes channel layers 115 (e.g., nanosheets), and sacrificial layers 113. The plurality of channel layers 115 can be comprised of, for example, Si. The plurality of sacrificial layers 113 can be comprised of SiGe, where Ge is in the percentage of 15 to 35%. The separating sacrificial layer 117 replaces the channel layer 115 near the top of the alternating layers, such that the separating sacrificial layer 117 is located between two different sacrificial layers 113. The separating sacrificial layer 117 can be comprised of SiGe, where Ge is in the percentage of 50 to 70%. The higher concentration of GE in the separating sacrificial layer 117 allows for the selective targeting of the layer of the sacrificial layers 113.

The first substrate 105 and the second substrate 108 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of semiconductor materials can be used as the semiconductor material of first substrate 105 and the second substrate 108. In some embodiments, first substrate 105 and the second substrate 108 includes both semiconductor materials and dielectric materials. The semiconductor first substrate 105 and the second substrate 108 may also comprise an organic semiconductor or a layered semiconductor such as, for example, Si/SiGe, a silicon-on-insulator or a SiGe-on-insulator. A portion or the entire semiconductor first substrate 105 and the second substrate 108 may also be comprised of an amorphous, polycrystalline, or monocrystalline. The semiconductor substrate 105 may be doped, undoped or contain doped regions and undoped regions therein.

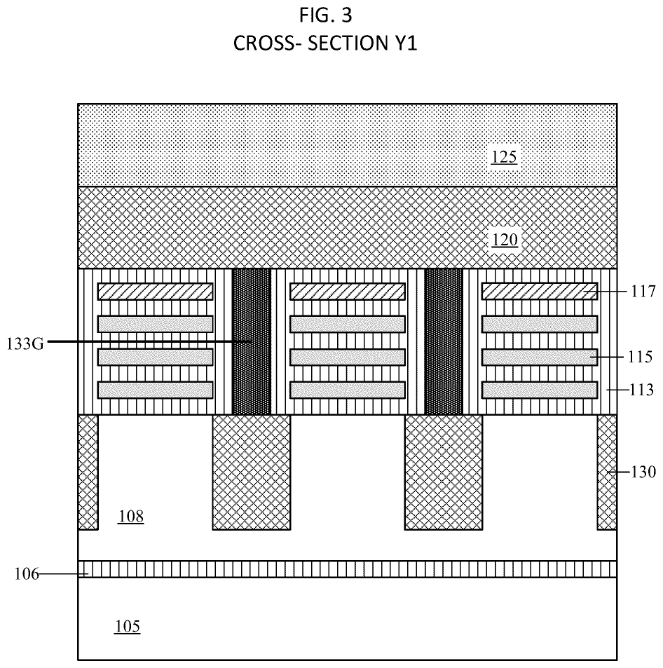

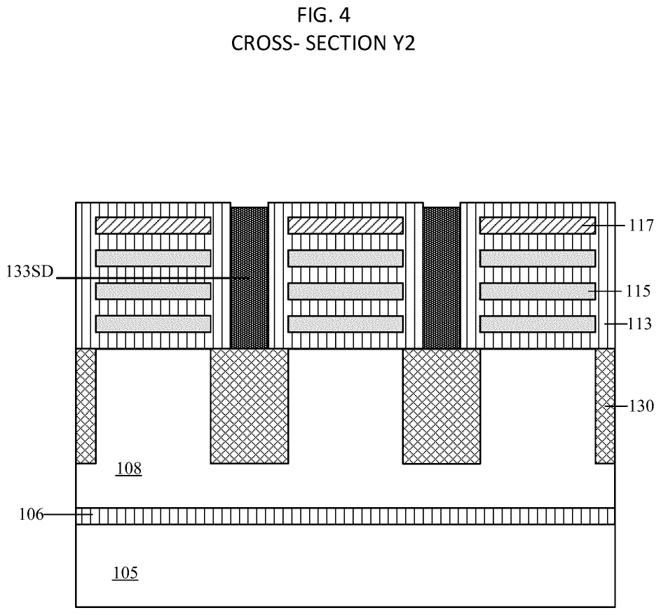

FIG. 3 illustrates the gate region of the nanosheet device after the formation of the of the dummy gate 120, hardmask 125, and dielectric pillars 133G, 133SD. The alternating layers were etched to form separate columns and the etching process forms a plurality of trenches (not shown) in the second substrate 108. These trenches (not shown) are filed in with a material to form the shallow trench isolation layer 130. The sacrificial layer 113 layers by adding additional material such that the sacrificial layers 113 are joined together and extends around the channel layers 115. The sacrificial layers 113 also extends around the separating sacrificial layer 117. A dielectric pillar 133G, 133SD is formed between sections of the sacrificial layer 133 that enclose different channel layers 110. The dielectric pillar 133G, 133SD extends from the gate regions (as illustrated in FIG. 3) into the source/drain region (as illustrated in FIG. 4). Dielectric pillar 133G refers to the portion of the dielectric pillar located in the gate region and dielectric pillar 133SD refers to the portion of the dielectric pillar located in the source/drain region. Dummy gate 120 is located on top of the sacrificial layer 113 and the dielectric pillar 133G. Hardmask 125 is located on top of dummy gate 120. FIG. 4 illustrates the source/drain region. The dummy gate 120 and the hardmask 125 have been removed from the source/drain region. The removal of these layers exposes the top surface of the sacrificial layer 113 and removal of these layers causes the pull down of the dielectric pillar 133SD. The removal of these layers causes a height difference in the dielectric pillar 133G in the gate region and the dielectric pillar 133SD.

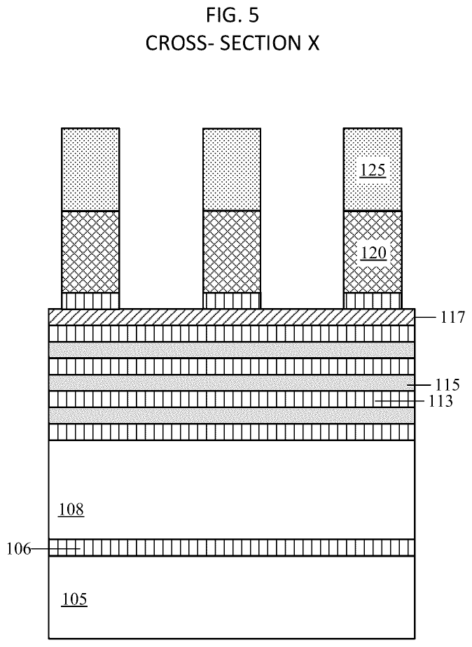

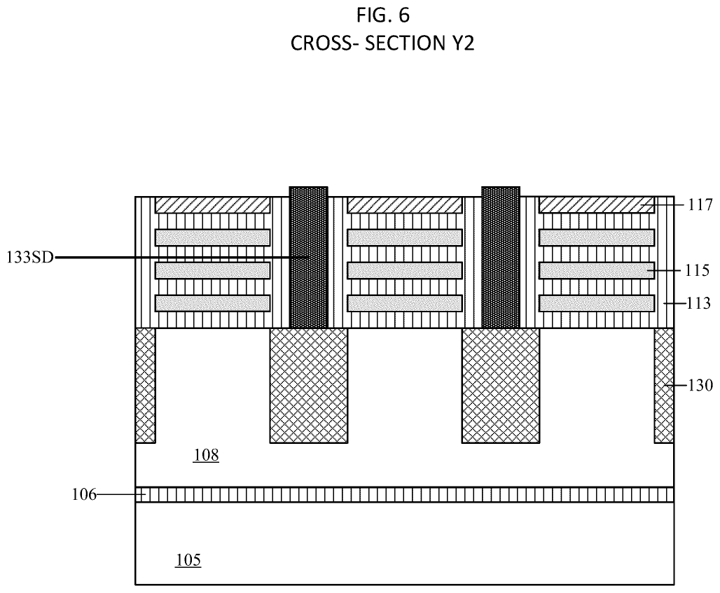

FIGS. 5 and 6 illustrate the processing stage after etching the top of the sacrificial layer 113. The portion of the sacrificial layer 113 is etched by, for example, reactive ion etch (RIE), to expose the separating sacrificial layer 117. A portion of the sacrificial layer 113 is still located beneath the dummy gate 120. FIG. 6 illustrates that the pull down of sacrificial layer 113 exposes the top surface of the separating sacrificial layer 117 and a portion of the dielectric pillar 133SD.

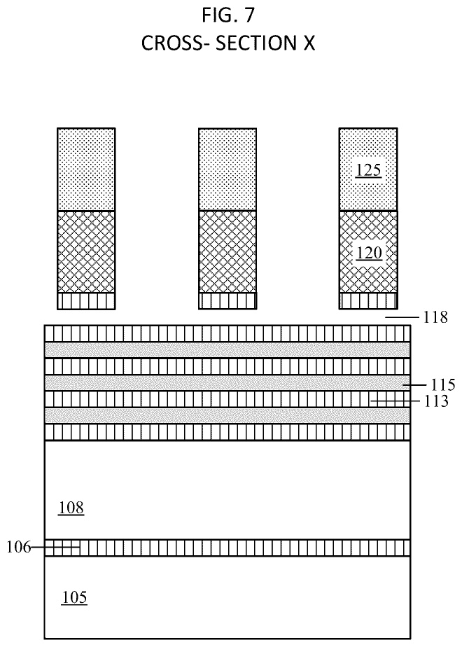

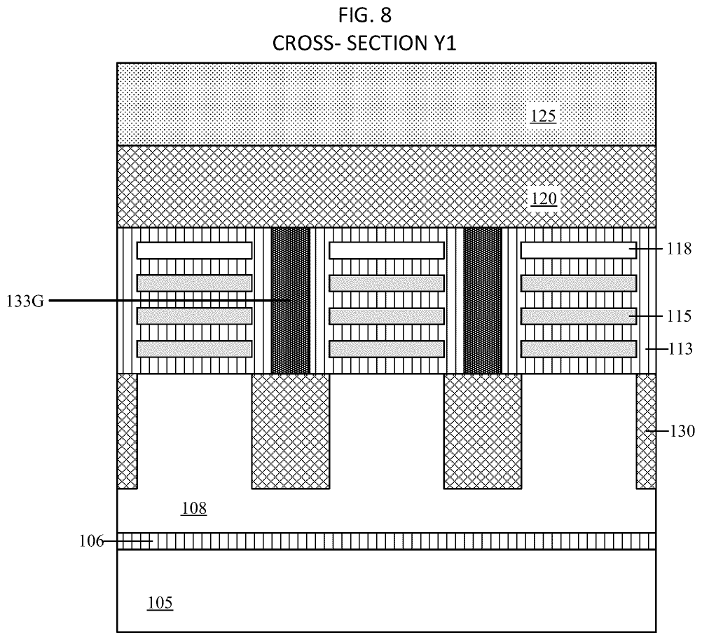

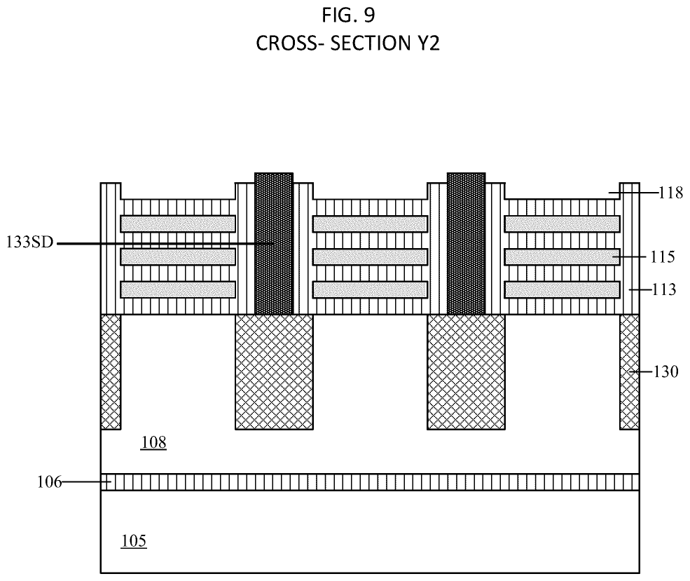

FIGS. 7, 8 and 9 illustrate the processing stage after removal of the sacrificial separating layer 117. The sacrificial separating layer 117 is selectively removed. The sacrificial separating layer 117 can be selectively removed because of the higher concentration of Ge when compared to the sacrificial layer 113. Gap 118 is created by the removal of the sacrificial separating layer 117 as illustrated in FIGS. 7, 8, and 9. Gap 118 is surrounded by the sacrificial layer 113 in the gate region as illustrated by FIG. 8 and gap 118 is more of exposed trench in the source/drain region as illustrated by FIG. 9.

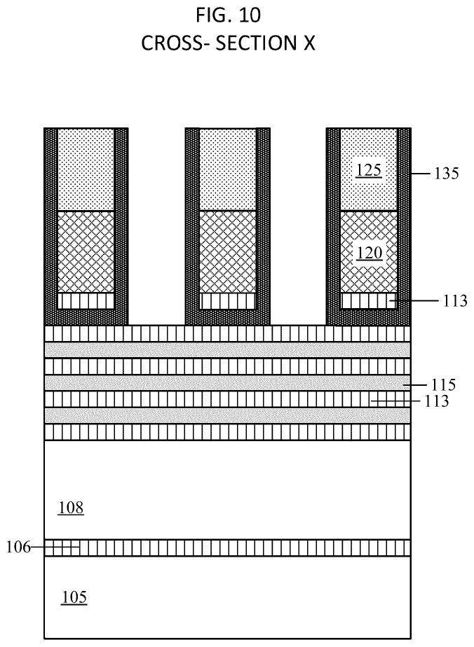

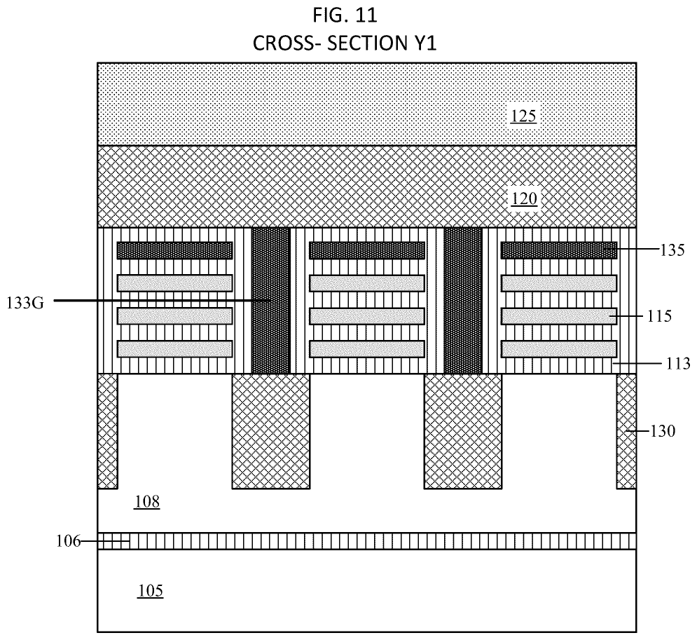

FIGS. 10 and 11 illustrate the processing stage after formation of gate spacer 135. Gate spacer 135 is formed on the exposed surfaces of the dummy gate 120, hardmask 125, and the top sacrificial layer 113. Gate spacer 135 fills in gap 118, thus the sacrificial layer surrounds a portion of the gate spacer 135, as illustrated in FIG. 11. Gate spacer 135 is etched back to remove it form the source/drain regions, while the gate spacer 135 remains located along the vertical sidewalls of the dummy gate 120 and the hardmask 125. Gate spacer 135 extends under a portion of the top sacrificial layer 113 as illustrated in FIG. 10. Sacrificial layer 113 surrounds a portion of the gate space 135 as illustrated in FIG. 11.

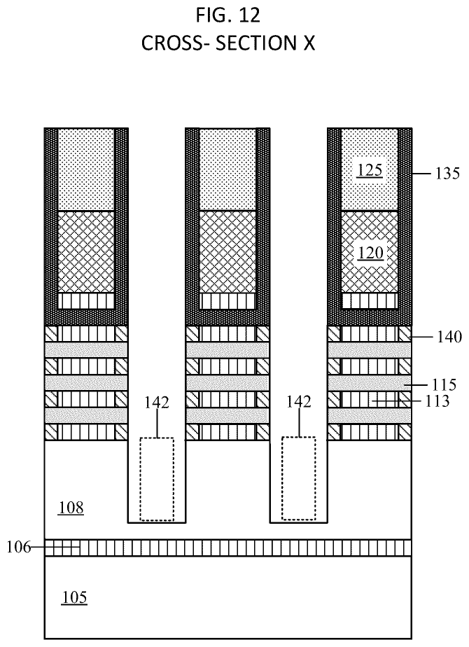

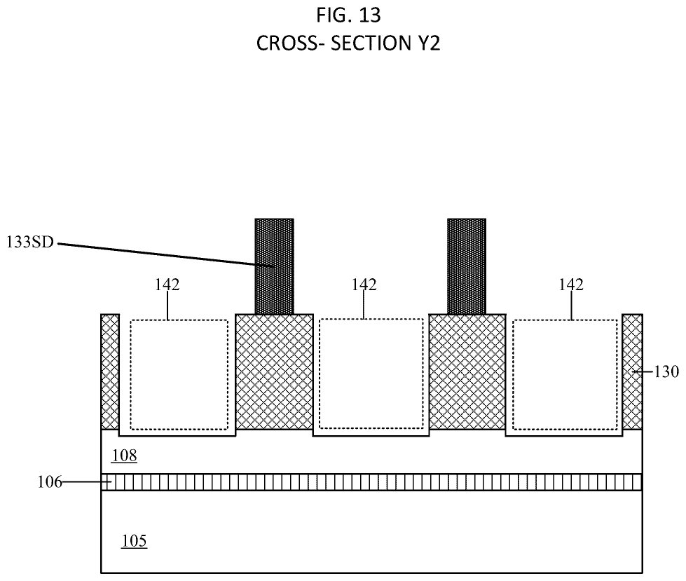

FIGS. 12 and 13 illustrate the processing stage after etching of the source/drain region, recessing of the sacrificial layers 113, formation of the inner spacer 140, and formation of the placeholder trenches 142. The alternating layers (i.e., channel layers 115 and sacrificial layers 113 are etched/removed to form the source/drain region. The removal of the alternating layer further reduces the height of the portion of the dielectric pillar 133SD located in the source/drain region. Sacrificial layers 113 are recessed to form gaps (not shown) around the ends of the channel layers. These gaps are filled in with a material to form the inner spacer 140. The second substrate 108 located within the source/drain region is etched to form the placeholder trenches 142.

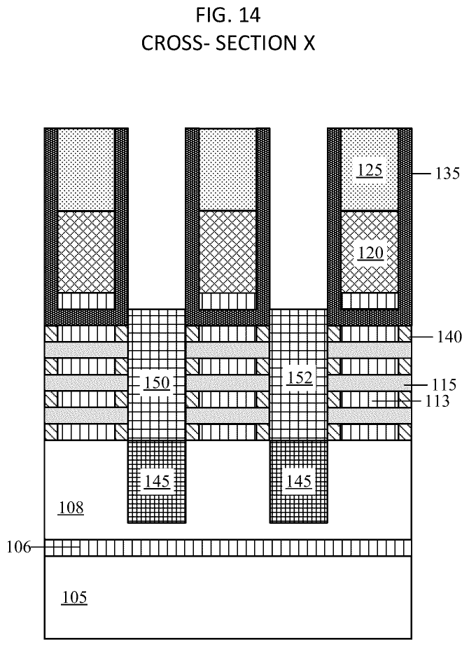

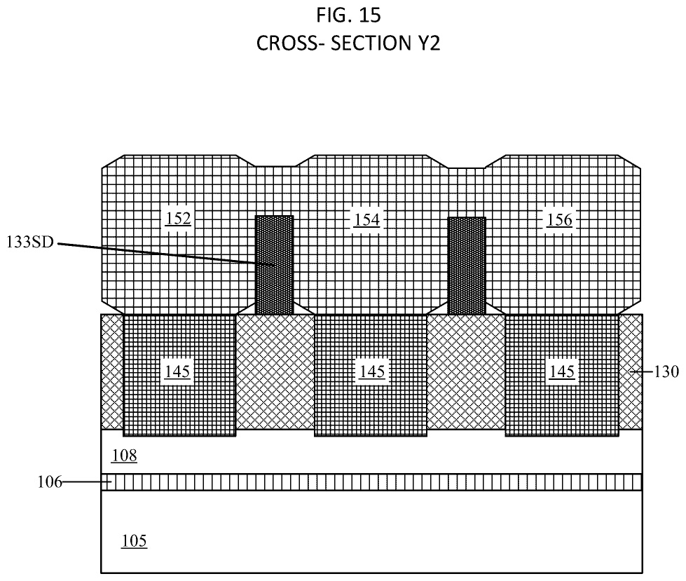

FIGS. 14 and 15 illustrate the processing stage after formation of the placeholders 145 and the formation of source/drains 150, 152, 154, 156. Placeholder trenches 142 are filled with a sacrificial material to form placeholders 145. Source/drains 150, 152, 154, 156 are epitaxially grown between columns of the alternating layers and on top of the placeholders 145, as illustrated in FIGS. 14 and 15. FIG. 15 illustrates the source/drain region that extends through multiple adjacent transistors. The reduced height of the dielectric pillar 133SD (caused by the frontside processing) will lead to the source/drain growing/extending over the top of the dielectric pillar 133SD. This means that adjacent source/drains 152, 154, 156 can merge or be in close proximity over the portion of the dielectric pillar 133SD located in the source/drain region. FIG. 15 illustrates the situation where adjacent source/drains 152, 154, 156 merged over the top of the dielectric pillars 133SD.

The source/drains 150, 152, 154, 156, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

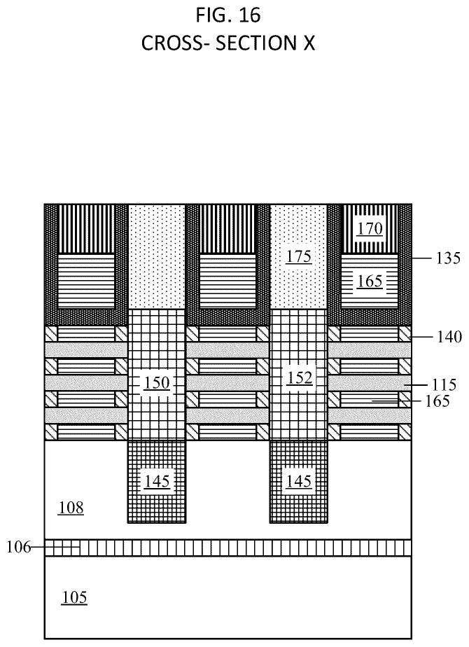

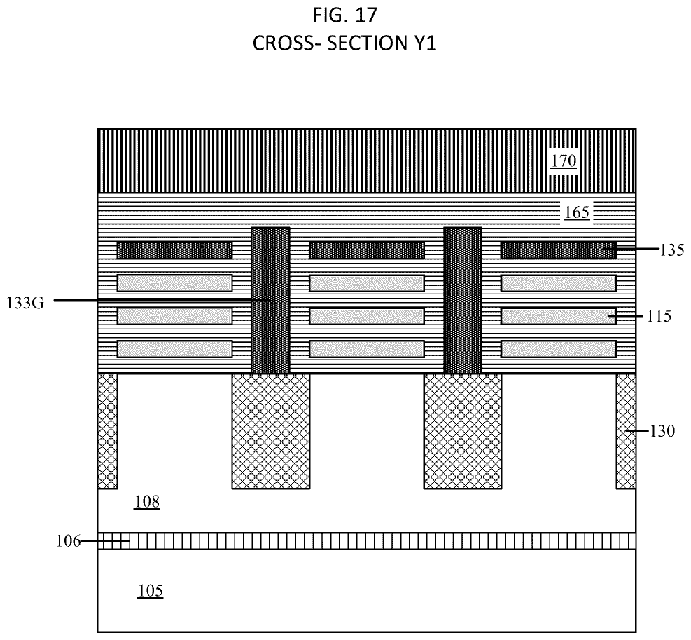

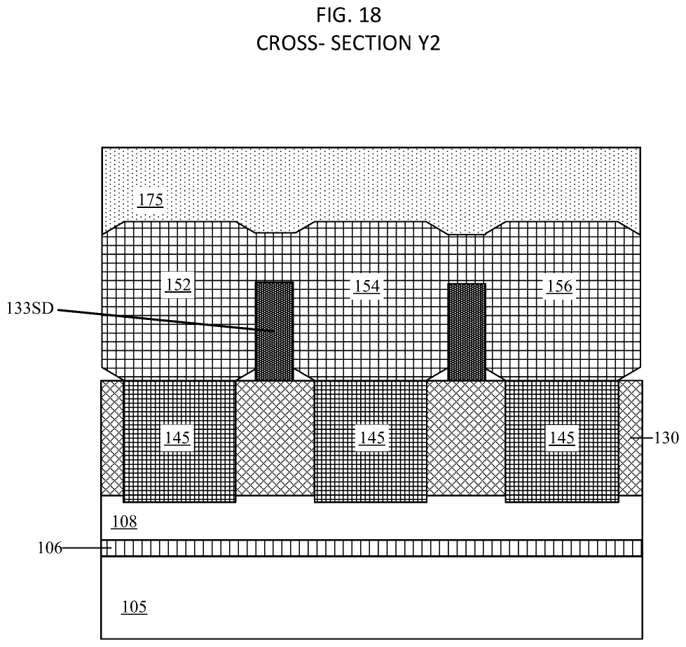

FIGS. 16, 17, and 18 illustrate the processing stage after formation of gate 165, the frontside interlayer dielectric layer 175, and the gate cap 170. A frontside interlayer dielectric layer 175 is formed on top of the source/drains 150, 152, 154, 156. Hardmask 125, dummy gate 120, and sacrificial layers 113 are removed to create an empty space (not shown) around the channel layers 110 and between segments of the gate spacer 135. Gate 165 is formed by filling this empty space with a gate material. Gate 165 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W. Additionally, gate cap 170 is formed on top of gate 165 and gate cap 170 is located between segments of the gate spacer 135. FIG. 17 illustrates that gate 165 surrounds a portion of gate spacer 135. Furthermore, gate 165 extends over the dielectric pillar 133G, thus forming a shared gate structure at this stage between multiple transistors.

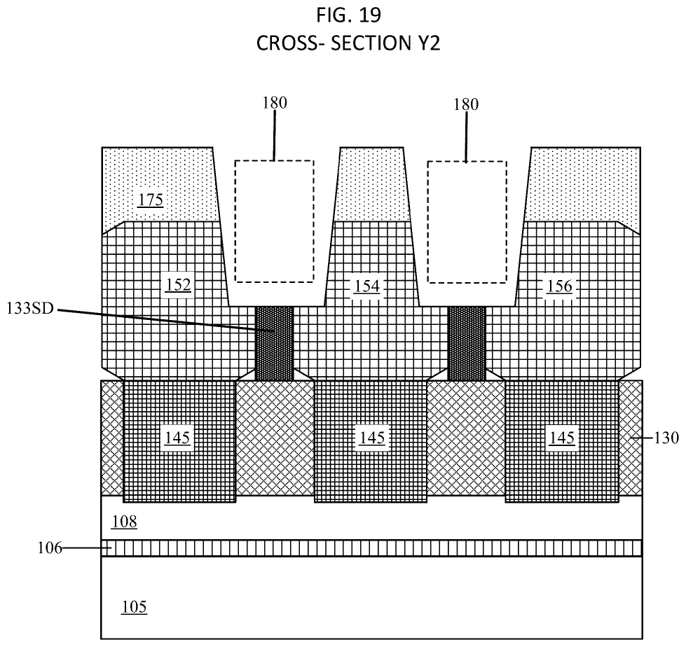

FIG. 19 illustrates the processing stage after formation of a source/drain cut trench 180. A lithography layer (not shown) is formed on top of the device. The lithography layer (not shown) and the underlying layers are patterned to form the source/drain cut trenches. The lithography layer is removed. FIG. 19 illustrates the processing stage after the lithography layer being removed. A source/drain cut trench 180 is formed in the frontside interlayer dielectric layer 175 and in the source/drains 152, 154, 156. The source/drain cut trench 180 separates the merged source/drains 152, 154, 156 into separate source/drains 152, 154, 156 by removed the connecting material. Source/drains cut trenches 180 are aligned with the dielectric pillar 133SD, such that the source/drain cut trench 180 exposes a top surface of the dielectric pillar 133SD. The source/drain cut trenches 180 changed the profile of each of the source/drains 152, 154, 156 as illustrated in FIG. 19. Depending on the location of the source/drains 152, 154, 156 and the locations of the source/drain cut trenches 180 different profiles in the source/drains 152, 154, 156 can be achieved. For example, source/drain 152 and source/drain 156 have mirror portions removed by the source/drain cut trench 180. Source/drain 152, 156 have a profile where there is horizontal top and an inclined surface towards the direction of the dielectric pillar 133SD. The source/drain cut trenches 180 creates a protrusion in source/drain 154. The protrusion in source/drain 154 is created by removing at least two sections of the source/drain 154 by at least two source/drain cut trenches 180. Each of the source/drain cut trenches 180 creates an inclined surface in the source/drain 154 towards a dielectric pillar 133SD. The profile/shape of the source/drain 154 looks like an inverted bolt (i.e., a head section and a shaft section, where the shaft section is the protrusion, when view from the illustrated cross-section Y2) where the source/drain cut trenches 180 are located adjacent to the shaft section. The changed profile in the source/drains 150, 152, 154, 156 changes the amount of surface area of the source/drain that is available for forming a connection with a frontside contact, which will be described in further detail below.

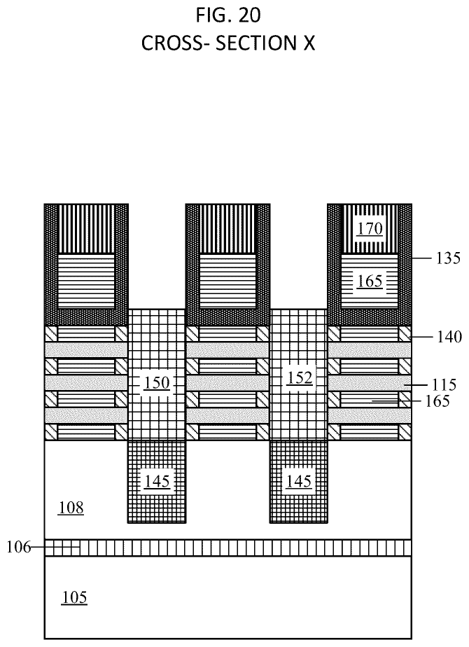

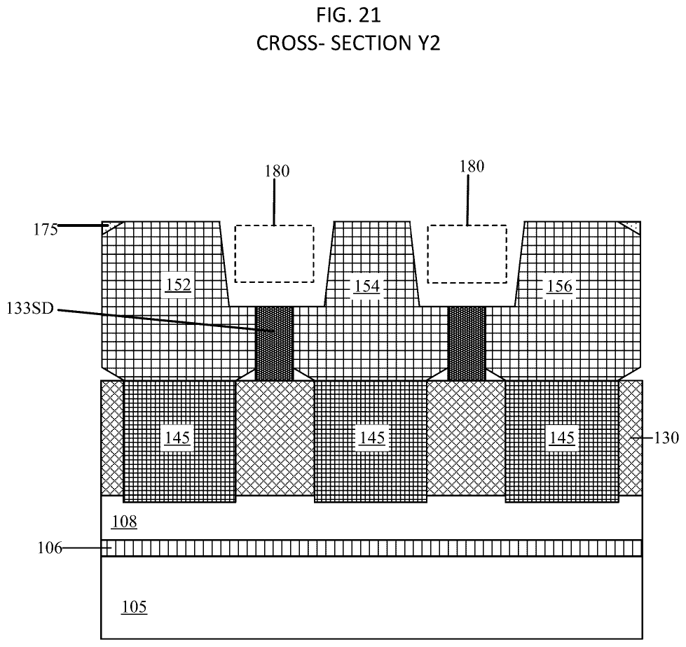

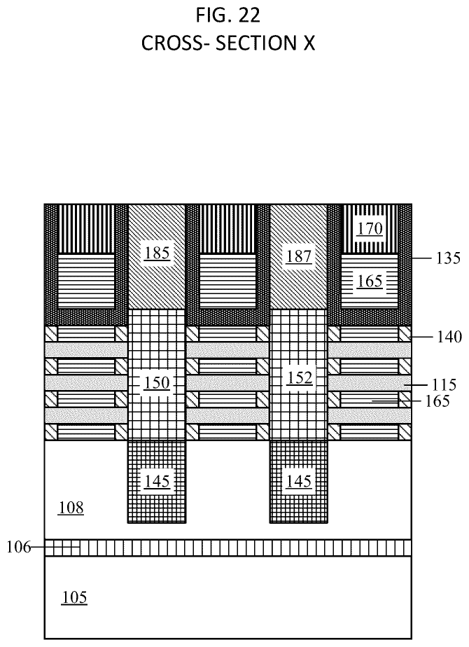

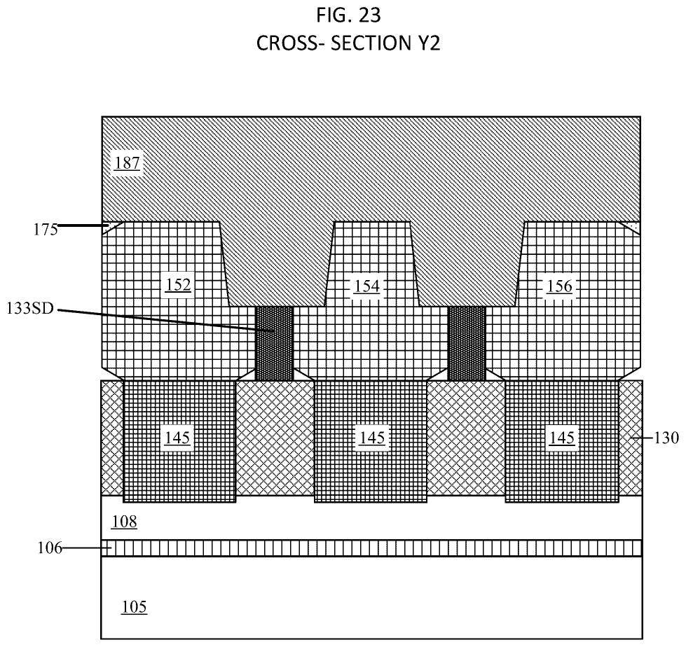

FIGS. 20 and 21 illustrate the processing stage after removal of the frontside interlayer dielectric layer 175 from the source/drain region. The frontside interlayer dielectric layer 175 is removed from the source/drain region to expose the top surfaces of the source/drains 150, 152, 154, 156. A portion of the frontside interlayer dielectric layer 175 could remain after the removal process, or the frontside interlayer dielectric layer 175 could be completely removed. FIGS. 22 and 23 illustrate the processing stage after formation of the shared contacts 185, 187 in the source/drain region. A metallization process forms a shared contacts 185, 187 in the source/drain region. The shared contacts 185, 187 are in contact with a plurality of the source/drains 150, 152, 154, 156, where the shared contacts are formed on top of the source/drains 150, 152, 154, 156. The shared contacts 185, 187 also extends into and fills the source/drain cut trenches 180. The shared contacts 185, 187 includes protrusion (i.e., the portion of the metal that filled the source/drain cut trenches 180) that extends downwards to contact the side of the source/drain 152, 154, 156 and the dielectric pillar 133SD. FIG. 23 illustrates the protrusion of the shared contact 185, 185 that are in contact with sides of the source/drains 152, 154, 156. FIG. 23 also illustrates that source/drain 154 is in contact with multiple protrusion because of the source/drain 154 being located between two adjacent source/drain cut trenches 180.

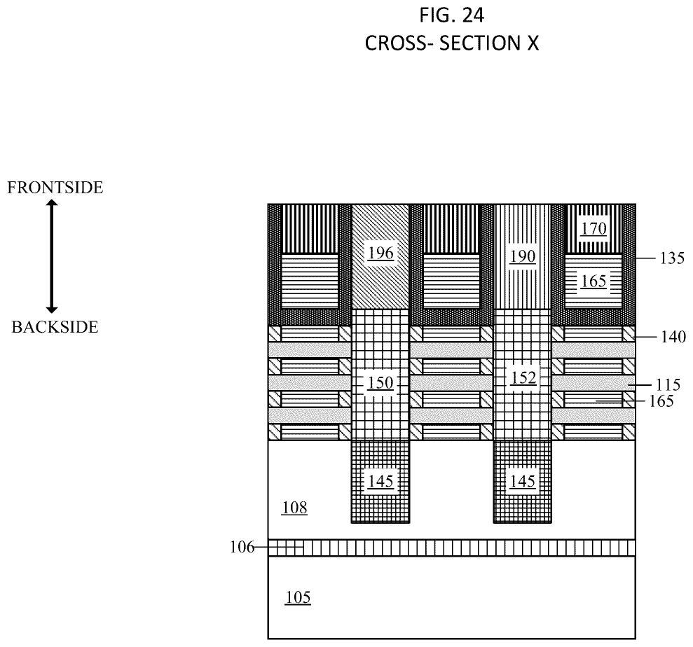

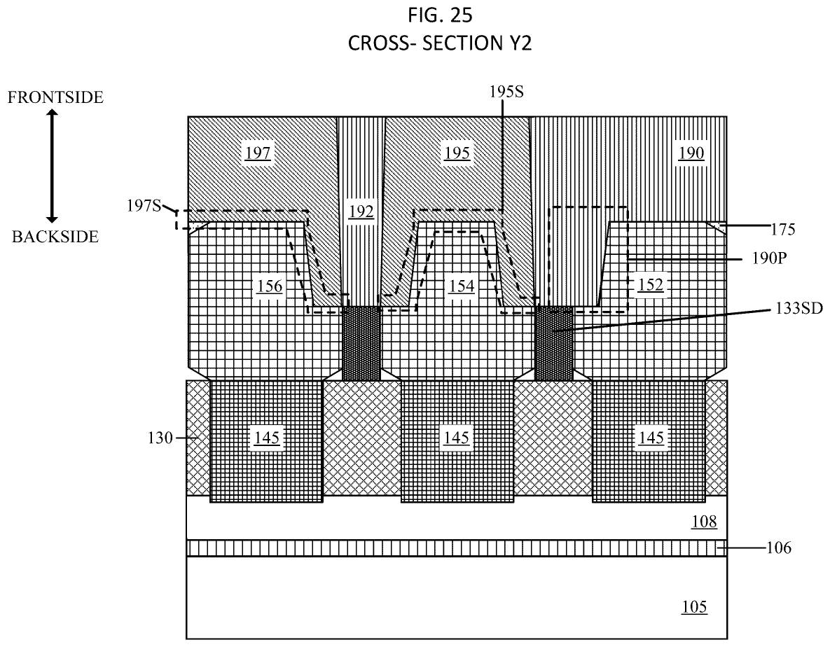

FIGS. 24 and 25 illustrate the processing stage after formation of the contact cuts 190, 192. Trenches (not shown) are formed in the shared contacts 185, 187 to separate the shared contacts 185, 187 into a plurality of source/drain contacts 195, 196, 197. The trenches are filled with a dielectric material to form contact cuts 190, 192. FIG. 25 illustrates two different types of contact cuts 190, 192. The first contact cut 190 has a horizontal section that extends along the top surface of the source/drain 152 and the first contact cut 190 has a protrusion section that extends along the inclined side of the source/drain 152. Dashed box 190P emphasized the protrusion section of the first contact cut that 190 that extends along the side of the source/drain 152. The first contact cut 190 side is in contact with the first source/drain contact 195. The bottom surface/backside surface of the protrusion of the first contact cut 190 is in contact with source/drain 152 and the dielectric pillar 133SD.

The second contact cut 192 extends downwards to the dielectric pillar 133SD to separate the two adjacent source drain contacts 195, 197. The first source/drain contact 195 is located between two contact cuts 190, 192 and located on top of source/drain 154. The first source/drain contact 195 has two protrusions that extend downwards around the sides of the protrusion (i.e., the shaft) of source/drain 154. Therefore, the first source/drain contact 195 has multiple surfaces that are in contact with the source/drain 154. Dashed box 195S emphasizes the contact surface area between the first source/drain contact 195 and source/drain 154. As illustrated in FIG. 25, the contact surface area between the first source/drain contact 195 and source/drain 154 has an inverted V-shape or U-shape profile. The second source/drain contact 197 is located on top of source/drain 156. The second source/drain contact 197 includes a horizontal section located on top of source/drain 156 and a protrusion section that is located adjacent to the inclined surface of the source/drain 156. A side surface and a bottom surface (i.e., the backside surface) of the protrusion of the second source/drain contact 197 is in contact with source/drain 156. The side wall of the second source/drain contact 197 is flush against the side of the second contact cut 192. Dash box 197S emphasized the contact surface area between the second source/drain contact 197 and source/drain 156.

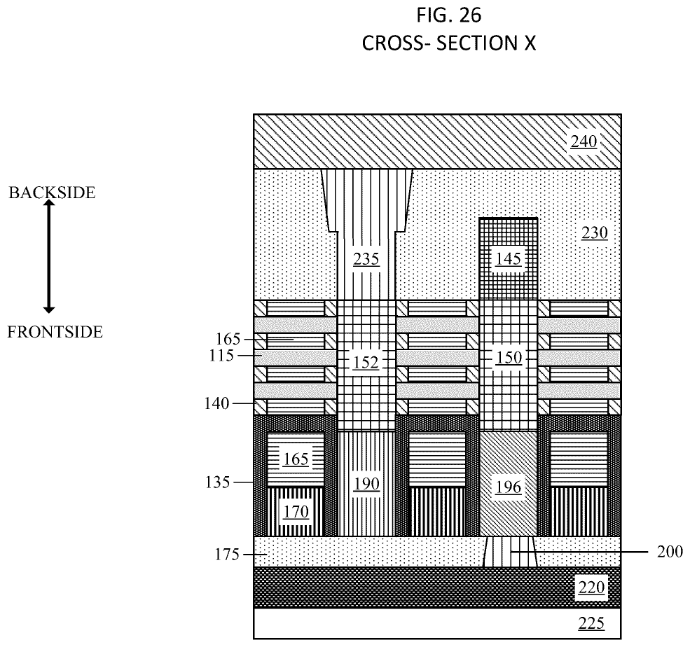

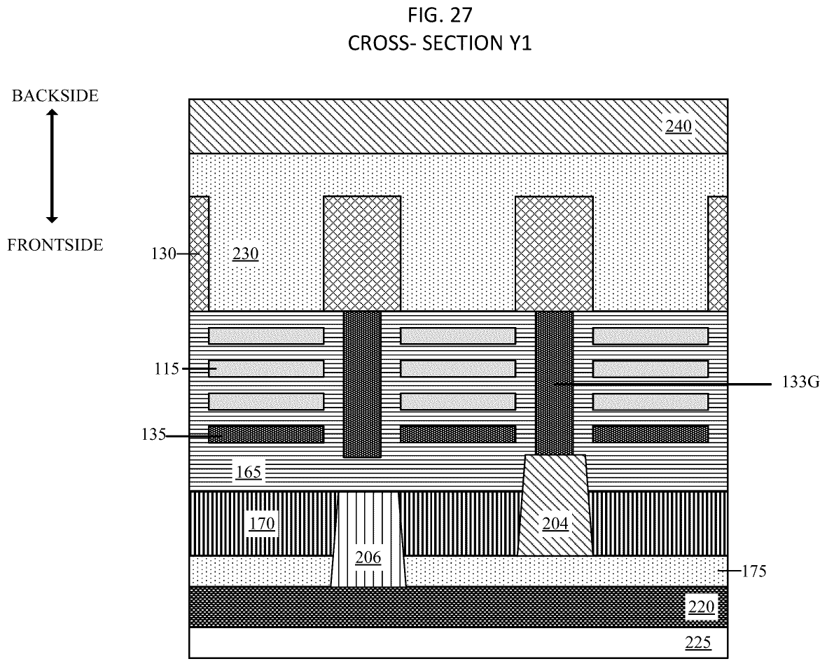

FIGS. 26, 27 and 28 illustrate the processing stage after backside processing of the nanosheet transistors. A lithography layer (not shown) is formed on top of the exposed source/drain contacts 195, 196, 197, gate cap 170, the contact cuts 190, 192, and gate spacer 135. A gate cut trench (not shown) is formed in gate cap 170 and gate 165 in the gate region. The gate cut trench (not shown) extends into the source/drain region such that the gate cut trench (not shown) is also formed in, the second contact cut 192, the first source/drain contact 195, and the second source/drain contact 197. The gate cut trench (not shown) extends downwards to the dielectric pillar 133G in the gate region and in the source/drain region the gate cut trench (not shown) extends downwards into the second contact cut 192, such that a portion of the second contact cut 192 is removed by the gate cut trench (not shown). Gate cut 204 is formed by filling the gate cut trench (not shown) with a dielectric material. Gate cut 204 is in contact with the portion of the dielectric pillar 133G located in the gate region. In the source/drain region, gate cut 204 has sidewalls that are in contact with the first and second source/drain contacts 195, 197, respectively. Furthermore, gate cut 204 in the source/drain region has a bottom surface that is wider than the width of the second contact cut 192 as emphasized by dashed box 258. The bottom surface or backside surface of the gate cut 204 in the source/drain region is in contact with the second contact cut 192, the first source/drain contact 195, and the second source/drain contact 197.

Additional frontside interlayer dielectric material is added to extend the height of the frontside interlayer dielectric layer 175 on top of the first source/drain contact 195, the second source/drain contact 197, gate cap 170, and the gate cut 204. A plurality of trenches (not shown) are formed in the frontside interlayer dielectric layer 175 and/or the gate cap 170. The plurality of trenches (not shown) are filled with a conductive material to form source/drain contact connection vias 200, 208, 209 and gate contact 206. An interconnect or back-end-of-the-line (BEOL) layer 220 is formed on top of the frontside interlayer dielectric layer 175, source/drain contact connection vias 200, 208, 209, and gate contact 206. A carrier wafer 225 is formed on top of the BEOL layer 220. The carrier wafer 225 allows for the nanosheet transistor to be flipped over for backside processing.

The backside processing removes the first substrate 105, the etch stop 106, and the second substrate 108. A backside interlayer dielectric layer 230 is formed on the exposed surfaces of the shallow trench isolation layer 130, placeholders 145, a backside surface of the gate 165, and a backside surface of the inner spacer 140. At least one trench (not shown) is formed in the backside interlayer dielectric layer 203 and each of the trenches (not shown) exposes a backside surface of one of the placeholders 145. The exposed placeholder 145 is selectively removed and exposes a backside surface of one of the source/drains, for example, source/drain 152. A metallization process fills the trench (not shown) and the valley/empty space created by the removal of the placeholder 145 with a conductive metal to form the backside source/drain contact 235. A backside interconnect or a backside-power-distribution-network (BSPDN) 240 is formed on top of the backside contact 235 and the backside interlayer dielectric layer 230.

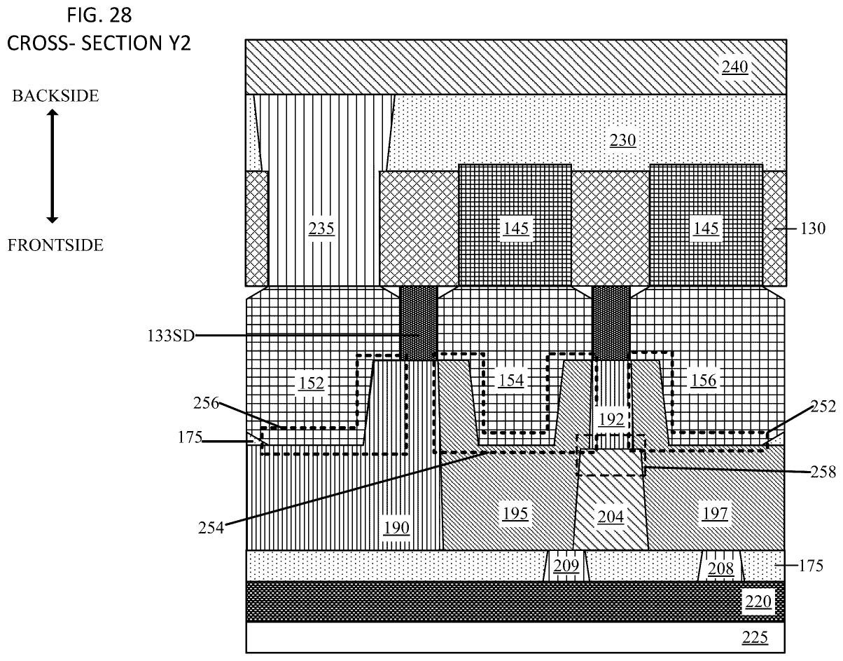

FIG. 28 illustrates a plurality of different component interactions. As mentioned above, dashed box 258 emphasizes the interaction between the gate cut 204 and the second contact cut 192. This interaction illustrates that the backside surface of the gate cut 204 is wider than the width of the second contact cut 192. This allows for the backside surface of the gate cut 204 to be in contact with the adjacent components (as seen in the illustrated embodiment, e.g., the first source/drain contact 195 and the second source/drain contact 197).

Dashed box 252 emphasizes a portion of the second source/drain contact 197. The emphasized portion of the second source/drain contact 197 includes a horizontal surface that is in contact with a horizontal surface (e.g., the frontside surface) of the source/drain 156. The emphasized portion also includes a protrusion of the second source/drain contact 197 that extends along an inclined side surface of the source/drain 156. This protrusion and the horizontal section of the emphasized portions of the second source/drain contact 197 illustrates the contact surface area between the source/drain 156 and the second source/drain contact 197. The contact surface area as emphasized by dashed box 252 has a substantially L-Shape. This L-shape contact surface area is greater than the contact surface area where the protrusion is not present. Furthermore, the second source/drain contact 197 has a surface that is in contact with the second contact cut 192 and at least one surface (FIG. 28 illustrates two surfaces) that is in contact with the gate cut 204.

Dashed box 256 emphasizes the interaction between source/drain 152 and the first contact cut 190. As explained above, the first contact cut 190 extends over the frontside surface of source/drain 152 and an inclined side surface of the source/drain 152. The first contact cut 190 includes a protrusion that is in contact with the inclined side surface of the source/drain 152. A backside surface of the protrusion of the first contact cut 190 is in contact with a frontside surface of the portion of the dielectric pillar 133SD that is located in the source/drain region.

Dashed box 254 emphasizes the portion of the first source/drain contact 195 that is in contact with source/drain 154. As described above, during the formation of the source/drain cut trench 180, the profile or shape of source/drain 154 is changed. The profile of source/drain 154 is changed such that a protrusion (e.g., the shaft) extends from a wider base (e.g., the head) structure (an up-side down or inverted bolt shape as seen in FIG. 19, or a bolt shape as seen in FIG. 28). First source/drain contact 195 includes at least two protrusions that are located next to the shaft/protrusion from source/drain 154. Dash box 254 emphasizes the U-shaped surface contact area between the source/drain 154 and the first source/drain contact 195. One of the protrusions of the first source/drain contact 195 is in contact with the second contact cut 192, gate cut 204, and source/drain 154. One of the protrusions of the first source/drain contact 195 is in contact with the first contact cut 190 and source/drain 154. By changing the profiles/shape of the source/drains 152, 154, 156 by forming trenches/valleys (e.g., source/drain cut trenches 180) in the source/drain 152, 154, 156 leads to an increase of available surface area of the source/drains 150, 152, 154, 156 for forming a connection with a frontside source/drain contact (e.g., first and second source/drain contact 195, 197).

A microelectronic structure that includes a first nanosheet transistor that includes a first source/drain 156. The first source/drain 156 includes a flat horizontal frontside surface and at least one inclined side surface (as emphasized by dashed box 252 in FIG. 28). A second nanosheet transistor that includes a second source/drain 154. The second source/drain 154 includes a flat horizontal frontside surface and at least one inclined side surface (as emphasized by dashed box 254 in FIG. 28). The first nanosheet transistor and the second nanosheet transistor are adjacent to each other (see, for example, FIG. 1), where the first source/drain 156 and the second source/drain 154 are aligned with each other through a common axis through a source/drain region (i.e., the illustrated cross-section Y2). A first frontside source/drain contact 197 that includes a horizontal section and a protrusion section (the protrusion section is located within dashed box 252, and the bottom surface of the horizontal section is located within dashed box 252). The horizontal section of the first frontside source/drain contact 197 is in contact with the flat horizontal frontside surface of the first source/drain 156. The protrusion section of the first frontside source/drain contact 197 is in contact with the at least one inclined side surface of the first source/drain 156 (as emphasized by dashed box 252). A second frontside source/drain contact 195 that includes a horizontal section and at least one protrusion section (one of the protrusion sections is located within dashed box 254, and the bottom surface of the horizontal section is located within dashed box 254). The horizontal section of the second frontside source/drain contact 195 is in contact with the flat horizontal frontside surface of the second source/drain 154. The at least one protrusion section of the second frontside source/drain contact 195 is in contact with the at least one inclined side surface of the second source/drain 154 (as emphasized by dashed box 254).

The second source/drain 154 includes at least two inclined side surfaces (as emphasized by dashed box 254). The second source/drain 154 has a bolt shape, where the at least two inclined side surfaces form the sides of the shaft of the bolt shape. The second frontside source/drain contact 195 includes at least two protrusion sections (as emphasized by dashed box 254). Each of the at least two protrusion sections of the second frontside contact 195 are in contact with one of the at least two inclined side surfaces of the second source/drain 154 (as emphasized by dashed box 254). The horizontal section of the second frontside source/drain contact 195 is located between the at least two protrusion section of the second frontside source/drain contact 195. The at least two protrusion sections and the horizontal section of the second frontside contact 195 form a U-Shape contact area with the second source/drain 154.

The horizontal section and the protrusion section of the first frontside source/drain contact 197 forms a L-shape contact area (as emphasized by dashed box 252) with the first source/drain 156.

A contact cut 192 located between the protrusion section of the first frontside source/drain contact 197 and the at least one protrusion section of the second frontside source/drain contact 195.

A microelectronic structure that includes a first nanosheet transistor that includes a first source/drain 156. The first source/drain 156 includes a flat horizontal frontside surface and at least one inclined side surface (as emphasized by dashed box 252 in FIG. 28). A second nanosheet transistor that includes a second source/drain 154. The second source/drain 154 includes a flat horizontal frontside surface and at least one inclined side surface (as emphasized by dashed box 254 in FIG. 28). The first nanosheet transistor and the second nanosheet transistor are adjacent to each other (see, for example, FIG. 1), where the first source/drain 156 and the second source/drain 154 are aligned with each other through a common axis through a source/drain region (i.e., the illustrated cross-section Y2). A first frontside source/drain contact 197 that includes a horizontal section and a protrusion section (the protrusion section is located within dashed box 252, and the bottom surface of the horizontal section is located within dashed box 252). The horizontal section of the first frontside source/drain contact 197 is in contact with the flat horizontal frontside surface of the first source/drain 156. The protrusion section of the first frontside source/drain contact 197 is in contact with the at least one inclined side surface of the first source/drain 156 (as emphasized by dashed box 252). A second frontside source/drain contact 195 that includes a horizontal section and at least one protrusion section (one of the protrusion sections is located within dashed box 254, and the bottom surface of the horizontal section is located within dashed box 254). The horizontal section of the second frontside source/drain contact 195 is in contact with the flat horizontal frontside surface of the second source/drain 154. The at least one protrusion section of the second frontside source/drain contact 195 is in contact with the at least one inclined side surface of the second source/drain 154 (as emphasized by dashed box 254). A contact cut 192 located between the protrusion section of the first frontside source/drain contact 197 and the at least one protrusion section of the second frontside source/drain contact 195. A gate cut 204 located on top of the contact cut 192, where the gate cut 204 is in contact with a side surface of the first frontside source/drain contact 197 and a side surface of the second frontside source/drain contact 295.

The second source/drain 154 includes at least two inclined side surfaces (as emphasized by dashed box 254). The second source/drain 154 has a bolt shape, where the at least two inclined side surfaces form the sides of the shaft of the bolt shape. The second frontside source/drain contact 195 includes at least two protrusion sections (as emphasized by dashed box 254). Each of the at least two protrusion sections of the second frontside contact 195 are in contact with one of the at least two inclined side surfaces of the second source/drain 154 (as emphasized by dashed box 254). The horizontal section of the second frontside source/drain contact 195 is located between the at least two protrusion section of the second frontside source/drain contact 195. The at least two protrusion sections and the horizontal section of the second frontside contact 195 form a U-Shape contact area with the second source/drain 154.

The horizontal section and the protrusion section of the first frontside source/drain contact 197 forms a L-shape contact area (as emphasized by dashed box 252) with the first source/drain 156.

A microelectronic structure that includes a first nanosheet transistor that includes a first source/drain 156. The first source/drain 156 includes a flat horizontal frontside surface and at least one inclined side surface (as emphasized by dashed box 252 in FIG. 28). A second nanosheet transistor that includes a second source/drain 154. The second source/drain 154 includes a flat horizontal frontside surface and at least one inclined side surface (as emphasized by dashed box 254 in FIG. 28). The first nanosheet transistor and the second nanosheet transistor are adjacent to each other (see, for example, FIG. 1), where the first source/drain 156 and the second source/drain 154 are aligned with each other through a common axis through a source/drain region (i.e., the illustrated cross-section Y2). A first frontside source/drain contact 197 that includes a horizontal section and a protrusion section (the protrusion section is located within dashed box 252, and the bottom surface of the horizontal section is located within dashed box 252). The horizontal section of the first frontside source/drain contact 197 is in contact with the flat horizontal frontside surface of the first source/drain 156. The protrusion section of the first frontside source/drain contact 197 is in contact with the at least one inclined side surface of the first source/drain 156 (as emphasized by dashed box 252). A second frontside source/drain contact 195 that includes a horizontal section and at least one protrusion section (one of the protrusion sections is located within dashed box 254, and the bottom surface of the horizontal section is located within dashed box 254). The horizontal section of the second frontside source/drain contact 195 is in contact with the flat horizontal frontside surface of the second source/drain 154. The at least one protrusion section of the second frontside source/drain contact 195 is in contact with the at least one inclined side surface of the second source/drain 154 (as emphasized by dashed box 254). A contact cut 192 located between the protrusion section of the first frontside source/drain contact 197 and the at least one protrusion section of the second frontside source/drain contact 195. A gate cut 204 located on top of the contact cut 192, where the gate cut 204 is in contact with a side surface of the first frontside source/drain contact 197 and a side surface of the second frontside source/drain contact 295. A backside surface of the gate cut 204 is wider than a frontside surface of the contact cut 192 (as emphasized by dashed box 258).

The backside surface of the gate cut 204 is further in contact with the protrusion section of the first frontside source/drain contact 197. The backside surface of the gate cut 204 is further in contact with the at least one protrusion section of the second frontside source/drain contact 195.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a first nanosheet transistor that includes a first source/drain, wherein the first source/drain includes a flat horizontal frontside surface and at least one inclined side surface;
a second nanosheet transistor that includes a second source/drain, wherein the second source/drain includes a flat horizontal frontside surface and at least one inclined side surface, wherein the first nanosheet transistor and the second nanosheet transistor are adjacent to each other, wherein the first source/drain and the second source/drain are aligned with each other through a common axis through a source/drain region;
a first frontside source/drain contact that includes a horizontal section and a protrusion section, wherein the horizontal section of the first frontside source/drain contact is in contact with the flat horizontal frontside surface of the first source/drain, wherein the protrusion section of the first frontside source/drain contact is in contact with the at least one inclined side surface of the first source/drain; and
a second frontside source/drain contact that includes a horizontal section and at least one protrusion section, wherein the horizontal section of the second frontside source/drain contact is in contact with the flat horizontal frontside surface of the second source/drain, wherein the at least one protrusion section of the second frontside source/drain contact is in contact with the at least one inclined side surface of the second source/drain.

2. The microelectronic structure of claim 1, wherein the second source/drain includes at least two inclined side surfaces.

3. The microelectronic structure of claim 2, wherein the second source/drain has a bolt shape, wherein the at least two inclined side surfaces form the sides of the shaft of the bolt shape.

4. The microelectronic structure of claim 3, wherein the second frontside source/drain contact includes at least two protrusion sections.

5. The microelectronic structure of claim 4, wherein each of the at least two protrusion sections of the second frontside contact are in contact with one of the at least two inclined side surfaces of the second source/drain.

6. The microelectronic structure of claim 5, wherein the horizontal section of the second frontside source/drain contact is located between the at least two protrusion section of the second frontside source/drain contact.

7. The microelectronic structure of claim 6, wherein the at least two protrusion sections and the horizontal section of the second frontside contact form a U-Shape contact area with the second source/drain.

8. The microelectronic structure of claim 1, wherein the horizontal section and the protrusion section of the first frontside source/drain contact forms a L-shape contact area with the first source/drain.

9. The microelectronic structure of claim 1, further comprising:
a contact cut located between the protrusion section of the first frontside source/drain contact and the at least one protrusion section of the second frontside source/drain contact.

10. A microelectronic structure comprising:
a first nanosheet transistor that includes a first source/drain, wherein the first source/drain includes a flat horizontal frontside surface and at least one inclined side surface;
a second nanosheet transistor that includes a second source/drain, wherein the second source/drain includes a flat horizontal frontside surface and at least one inclined side surface, wherein the first nanosheet transistor and the second nanosheet transistor are adjacent to each other, wherein the first source/drain and the second source/drain are aligned with each other through a common axis through a source/drain region;
a first frontside source/drain contact that includes a horizontal section and a protrusion section, wherein the horizontal section of the first frontside source/drain contact is in contact with the flat horizontal frontside surface of the first source/drain, wherein the protrusion section of the first frontside source/drain contact is in contact with the at least one inclined side surface of the first source/drain;
a second frontside source/drain contact that includes a horizontal section and at least one protrusion section, wherein the horizontal section of the second frontside source/drain contact is in contact with the flat horizontal frontside surface of the second source/drain, wherein the at least one protrusion section of the second frontside source/drain contact is in contact with the at least one inclined side surface of the second source/drain;
a contact cut located between the protrusion section of the first frontside source/drain contact and the at least one protrusion section of the second frontside source/drain contact; and
a gate cut located on top of the contact cut, wherein the gate cut is in contact with a side surface of the first frontside source/drain contact and a side surface of the second frontside source/drain contact.

11. The microelectronic structure of claim 10, wherein the second source/drain includes at least two inclined side surfaces.

12. The microelectronic structure of claim 11, wherein the second source/drain has a bolt shape, wherein the at least two inclined side surfaces form the sides of the shaft of the bolt shape.

13. The microelectronic structure of claim 12, wherein the second frontside source/drain contact includes at least two protrusion sections.

14. The microelectronic structure of claim 13, wherein each of the at least two protrusion sections of the second frontside contact are in contact with one of the at least two inclined side surfaces of the second source/drain.

15. The microelectronic structure of claim 14, wherein the horizontal section of the second frontside source/drain contact is located between the at least two protrusion section of the second frontside source/drain contact.

16. The microelectronic structure of claim 15, wherein the at least two protrusion sections and the horizontal section of the second frontside contact form a U-Shape contact area with the second source/drain.

17. The microelectronic structure of claim 16, wherein the horizontal section and the protrusion section of the first frontside source/drain contact forms a L-shape contact area with the first source/drain.

18. A microelectronic structure comprising:
a first nanosheet transistor that includes a first source/drain, wherein the first source/drain includes a flat horizontal frontside surface and at least one inclined side surface;
a second nanosheet transistor that includes a second source/drain, wherein the second source/drain includes a flat horizontal frontside surface and at least one inclined side surface, wherein the first nanosheet transistor and the second nanosheet transistor are adjacent to each other, wherein the first source/drain and the second source/drain are aligned with each other through a common axis through a source/drain region;
a first frontside source/drain contact that includes a horizontal section and a protrusion section, wherein the horizontal section of the first frontside source/drain contact is in contact with the flat horizontal frontside surface of the first source/drain, wherein the protrusion section of the first frontside source/drain contact is in contact with the at least one inclined side surface of the first source/drain;
a second frontside source/drain contact that includes a horizontal section and at least one protrusion section, wherein the horizontal section of the second frontside source/drain contact is in contact with the flat horizontal frontside surface of the second source/drain, wherein the at least one protrusion section of the second frontside source/drain contact is in contact with the at least one inclined side surface of the second source/drain;
a contact cut located between the protrusion section of the first frontside source/drain contact and the at least one protrusion section of the second frontside source/drain contact; and
a gate cut located on top of the contact cut, wherein the gate cut is in contact with a side surface of the first frontside source/drain contact and a side surface of the second source/drain contact, wherein a backside surface of the gate cut is wider than a frontside surface of the contact cut.

19. The microelectronic structure of claim 18, wherein the backside surface of the gate cut is further in contact with the protrusion section of the first frontside source/drain contact.

20. The microelectronic structure of claim 19, wherein the backside surface of the gate cut is further in contact with the at least one protrusion section of the second frontside source/drain contact.
